(19) United States
(12) Patent Application Publication
(10) Pub. No.: US 2009/0071918 A1
(43) Pub. Date: Mar. 19, 2009

(54) VERTICAL SEMICONDUCTOR WAFER CARRIER

(76) Inventors: Panchapakesan Ramanarayanan, Sunnyvale, CA (US); Karson Knutson, Beaverton, OR (US); Peter G. Tolchinsky, Beaverton, OR (US); Christopher Parker, Hillsboro, OR (US)

Correspondence Address: INTEL CORPORATION;c/o INTELLEVATE, LLC, P.O. BOX 52050, MINNEAPOLIS, MN, 55402, US

(21) Appl. No.: 11/857,398

(22) Filed: Sep. 18, 2007

(51) Int. Cl. H01L 21/00

(52) U.S. Cl. 211/41.18

(57) ABSTRACT

A vertical semiconductor wafer carrier comprises a circular base, a first wafer support rod mounted at a first position proximate a perimeter of the circular base, a second wafer support rod mounted at a second position proximate the perimeter of the circular base, wherein an angle θ₁₂ formed between the first position and the second position relative to a center of the circular base is around 20°, a third wafer support rod mounted at a third position proximate the perimeter of the circular base, and a fourth wafer support rod mounted at a fourth position proximate the perimeter of the circular base, wherein an angle θ₃₄ formed between the third position and the fourth position relative to the center of the circular base is around 20°, and wherein an angle θ₁₄ formed between the first and fourth positions relative to the center of the circular base is around 180°.

### BACKGROUND

In the manufacture of integrated circuits, vertical support carriers are used to expose an array of semiconductor wafers to gases, including but not limited to deposition gases. Within a vertical support carrier, a support structure, known as a wafer boat, is used to hold the array of semiconductor wafers. The array of wafers are arranged in a stacked configuration. The wafer boat uses three or four equally spaced support rods to carry the wafer stack. The support rods are formed of quartz and include grooves in which the wafers are held.

In conventional wafer boats, the semiconductor wafers being held by the support rods suffer from wafer bowing and wafer stress due to gravity. As the diameter of semiconductor wafers increases to 300 mm and greater, the wafer bowing and wafer stress become more severe. Therefore, improved wafer carriers are needed to reduce bowing and stress on the semiconductor wafer due to gravity.

### BRIEF DESCRIPTION OF THE DRAWINGS

FIG. 1A illustrates a vertical furnace.

FIG. 1B illustrates a conventional support structure within a vertical furnace.

FIG. 1C is a cross-sectional top view of the conventional support structure shown in FIG. 1B.

FIG. 2 is a cross-sectional top view of a vertical wafer carrier constructed in accordance with an implementation of the invention.

FIG. 3 illustrates the vertical wafer carrier of FIG. 2 within a semiconductor processing tool.

FIGS. 4A and 4B provide data illustrating how the vertical wafer carrier of the invention reduces wafer bowing and wafer stress.

### DETAILED DESCRIPTION

Described herein is a vertical wafer carrier that may be used to mount semiconductor wafers within a semiconductor processing tool, such as vertical furnace. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Implementations of the invention provide a novel vertical wafer carrier to hold an array of semiconductor wafers within a semiconductor processing tool. The vertical wafer carrier of the invention utilizes four support rods that are positioned at strategic locations around the wafer to reduce wafer stress and reduce wafer bowing.

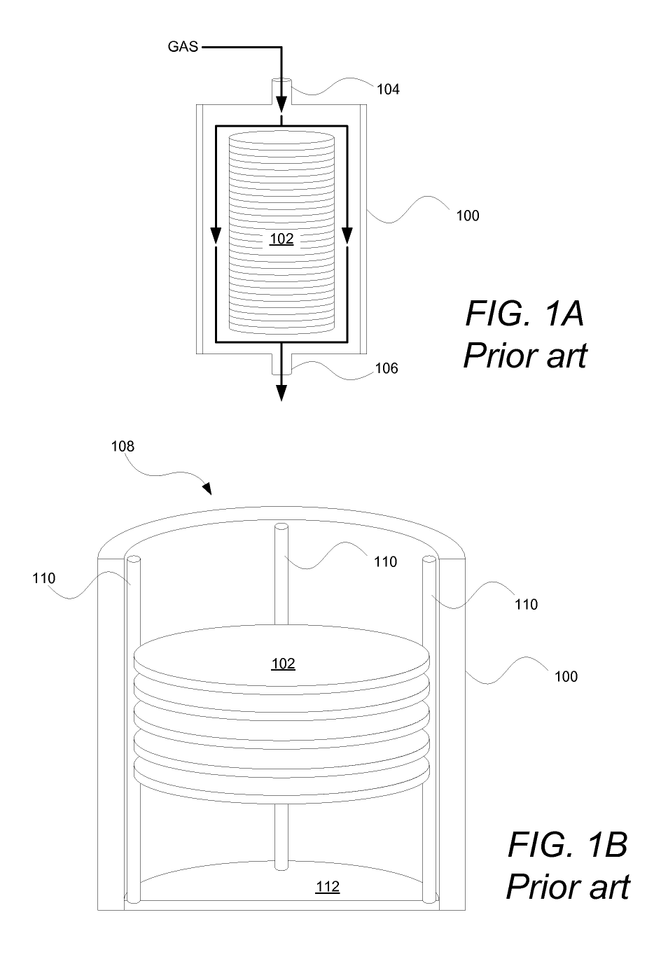

By way of background, FIG. 1A illustrates a vertical furnace 100, which is one example of a conventional semiconductor processing tool that uses a vertical wafer carrier. A stacked array of semiconductor wafers 102 is mounted within the vertical furnace 100. As will be known to those of skill in the art, each semiconductor wafer 102 is generally a wafer of silicon crystal that has a diameter of 200 mm or 300 mm. Wafers that are larger than 300 mm may also be used.

The array of wafers 102 may be exposed to deposition gases or other types of gases within the vertical furnace 100. As shown in FIG. 1A, gases typically flow into the vertical furnace 100 at an inlet 104 and are exhausted at an outlet 106. The gases flow over the surfaces of the array of wafers 102 as they travel through the vertical furnace 100. Processes that may be used in such a furnace include, but are not limited to, gas flow of reactive species used for deposition, gas flow of inert species used for anneals, and gas flow of species used for ionized plasma processing.

FIG. 1B illustrates a conventional wafer support structure 108 used in a semiconductor processing tool, such as the vertical furnace 100 of FIG. 1A. The support structure 108 is used to mount the array of wafers 102 within a semiconductor processing tool. The support structure 108 is conventionally known as a “wafer boat”. As shown, the support structure 108 consists of three support rods 110. Each support rod 110 includes an array of grooves (not shown) or another feature upon which the wafers 102 may be loaded and held. The support rods 110 are generally formed from a quartz material and the ends of the support rods 110 are mounted onto a quartz plate 112 or a quartz ring (not shown).

FIG. 1C is a cross sectional top-view of the support structure 108. As shown, the support rods 110 are arranged in a semi-circle around the perimeter of the quartz plate 112 and are spaced equally apart. A first support rod 110-1 and a second support rod 110-2 are mounted at opposite ends of the plate 112 such that an angle θ_{A} between the two support rods, measured with respect to a center point 114 of the quartz plate 112, is approximately 180°. If the angle θ_{A} happens to be greater than 180°, the wafers 102 cannot be loaded into the support structure 108. A third support rod 110-3 is mounted approximately halfway between the first and second support rods 110-1 and 110-2. As such, an angle θ_{B} between the third support rod 110-3 and each of the first and second support rods 110-1 and 110-2, measured relative to the center point 114, is approximately 90°.

As noted above, during a process carried out in a semiconductor processing tool, support rods 110 mounted in the conventional orientation shown in FIG. 1C allow gravity to induce mechanical stress on the semiconductor wafer 102. This causes wafer bowing and wafer stress in the semiconductor wafers 102, especially when the semiconductor wafers 102 have a relatively large diameter. Alternate support structures 108 exist that use four support rods 110, but these support rods 110 are also spaced equally apart around the semicircle (i.e., the support rods are 60° apart) and still allow gravity to induce stress on the wafers 102.

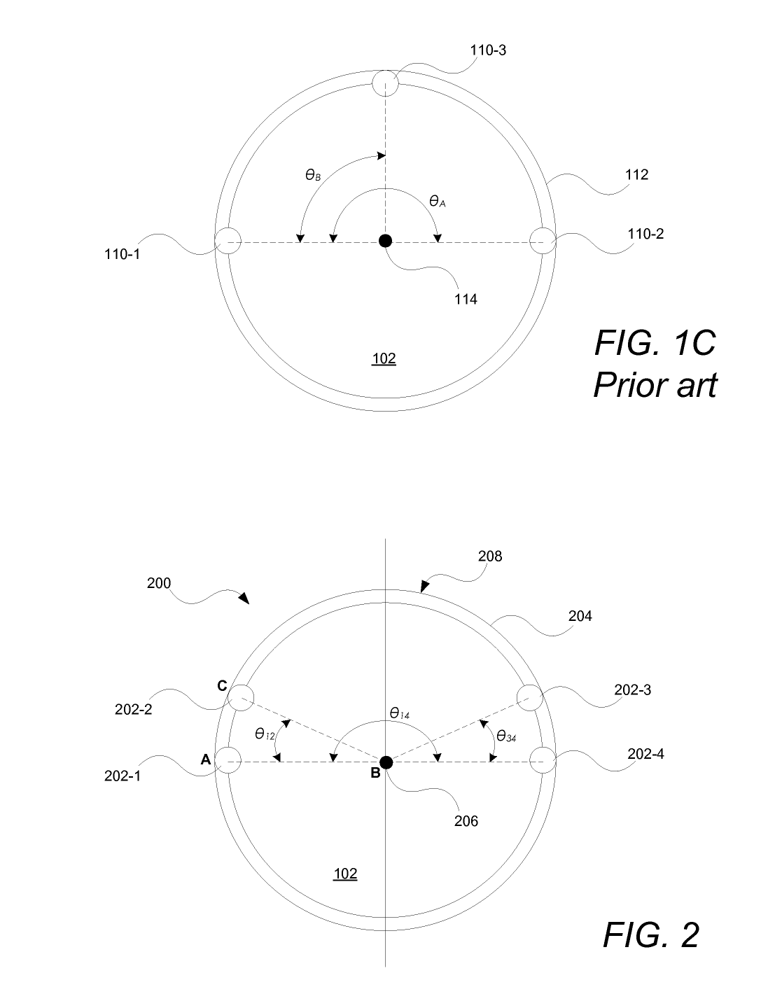

FIG. 2 is a cross-sectional top view of a vertical wafer carrier 200 constructed in accordance with implementations of the invention. The vertical wafer carrier 200 is designed to reduce wafer bowing and wafer stress caused by gravity. The vertical wafer carrier 200 of the invention may be used within any semiconductor processing tool that can accommodate a stacked array of semiconductor wafers.

As shown, the vertical wafer carrier 200 utilizes four wafer support rods 202 that are mounted on a support plate 204. The wafer support rods 202 are denoted in FIG. 2 as wafer support rods 202-1, 202-2, 202-3, and 202-4. For purposes of this description, the angle between any two of the support rods 202 is measured with respect to a center point 206 of the support plate 204, such that the center point 206 is the vertex of the angle. For instance, if the location of the wafer support rod 202-1 is denoted as “A”, the center point 206 of the support plate 204 is denoted as “B”, and the wafer support rod 202-2 is denoted as “C”, the angle θ₁₂ between support rods 202-1 and 202-2 is angle ∠ABC. This is shown in FIG. 2.

The wafer support rods 202 of the invention are formed in a substantially identical manner to conventional wafer support rods. As such, the wafer support rods 202 are formed from conventional materials used in the art, including but not limited to materials such as quartz, silicon, silicon carbide, other hardened materials that may be used in wafer boats. Similar to conventional support rods, the wafer support rods 202 of the invention also include an array of grooves or another feature adapted to receive an array of wafers, thereby providing a structure upon which the wafers 102 may be loaded and held. The support plate 204 of the invention may be formed from the same list of materials available for the wafer support rods. In some implementations, a support ring may by used instead of a support plate.

In accordance with an implementation of the invention, the four wafer support rods 202 are positioned at locations proximate or adjacent to a perimeter 208 of the support plate 204 that reduce wafer bowing and stress. The first wafer support rod 202-1 is mounted at a first position proximate to the perimeter 208 and the fourth wafer support rod 202-4 is mounted at a fourth position proximate to the perimeter 208. An angle θ₁₄, measured between support rod 202-1 and support rod 202-4, is approximately 180°. Therefore, the segment of the perimeter 208 between support rod 202-1 and support rod 202-4 defines a semicircle. As noted above, the angle θ₁₄ needs to be around 180° or less to allow for wafer loading and unloading.

Unlike conventional support structures, the remaining two support rods 202-2 and 202-3 are not mounted at locations that cause all of the wafer support rods 202 to be spaced equally apart. Rather, in accordance with implementations of the invention, the second support rod 202-2 is mounted at a position proximate to the perimeter 208 that is relatively close to the first wafer support rod 202-1. Similarly, in accordance with implementations of the invention, the third support rod 202-3 is mounted at a position proximate to the perimeter 208 that is relatively close to the fourth wafer support rod 202-4. The angle between the first support rod 202-1 and the second support rod 202-2 is denoted as angle θ₁₂. The angle between the third support rod 202-3 and the fourth support rod 202-4 is denoted as angle θ₃₄.

In accordance with implementations of the invention, as the angles θ₁₂ and θ₃₄ are reduced, the amount of wafer bow and wafer stress that is caused by gravity is also reduced. Therefore, in implementations of the invention, the vertical wafer carrier 200 is configured such that the angles θ₁₂ and θ₃₄ are greater than 0° but less than 60°. In further implementations, the vertical wafer carrier 200 is configured such that the angles θ₁₂ and θ₃₄ are greater than 0° but less than or equal to 45°. In still further implementations, the vertical wafer carrier 200 is configured such that the angles θ₁₂ and θ₃₄ are greater than 0° but less than or equal to 30°. And in further implementations, the vertical wafer carrier 200 is configured such that the angles θ₁₂ and θ₃₄ are greater than 0° but less than 20°.

In accordance with implementations of the invention, the angles θ₁₂ and θ₃₄ are reduced to a value that is as close to 0° as possible while maintaining sufficient balance and support for the semiconductor wafer 102 such that manufacturing processes are not affected. Positioning the support rods 202 in this orientation provides support for the semiconductor wafers 102 with lower wafer stress and bowing relative to conventional wafer boats. In one implementation, a compromise that provides relatively small angles θ₁₂ and θ₃₄ while maintaining sufficient wafer balance and support is found by setting the angles θ₁₂ and θ₃₄ to a value around 20°.

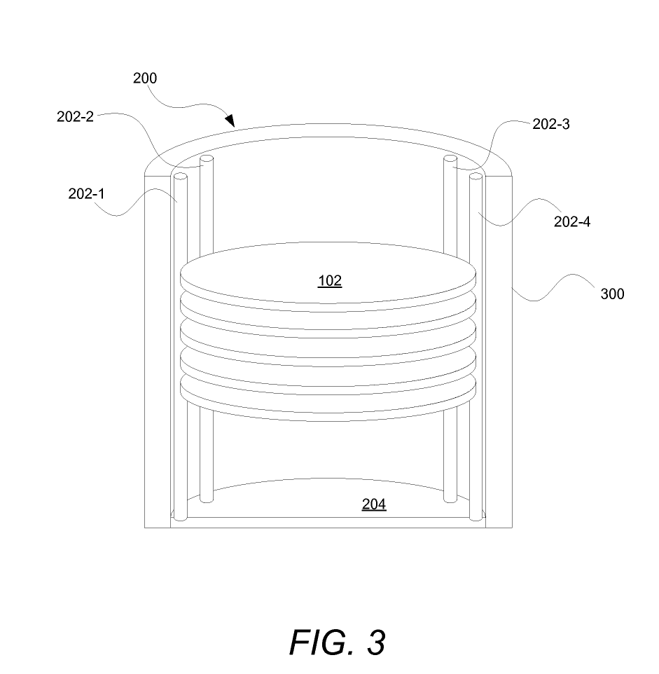

FIG. 3 illustrates a perspective view, similar to FIG. 1B, of a semiconductor processing tool 300 that utilizes a vertical wafer carrier 200 constructed in accordance with implementations of the invention. As shown, the support rods 202 are positioned in accordance with FIG. 2.

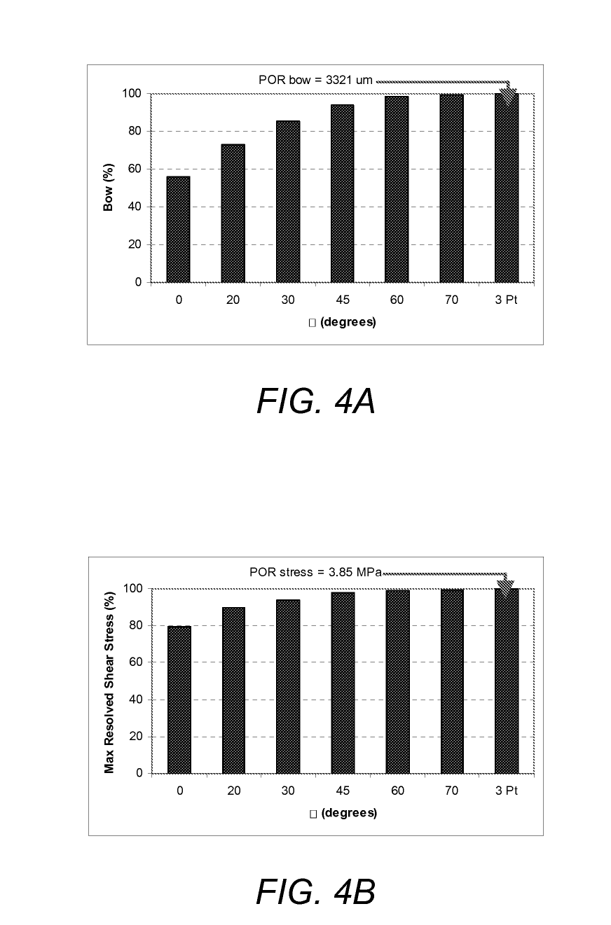

FIGS. 4A and 4B are graphs illustrating how reducing the value of angles θ₁₂ and θ₃₄ leads to reduced wafer bowing and wafer stress. FIG. 4A illustrates how a vertical wafer carrier using three equally-spaced support rods (i.e., angle θ₁₂ or θ₃₄ equals 90°) causes 3321 μm of wafer bow. FIG. 4A also illustrates that as the value of angles θ₁₂ and θ₃₄ decreases, the amount of wafer bow decreases as well. As demonstrated by FIG. 4A, when the angles θ₁₂ and θ₃₄ are at or near zero, the amount of wafer bow is reduced by around 45%.

FIG. 4B illustrates how a vertical wafer carrier using three support rods (i.e., angle θ₁₂ or θ₃₄ equals 90°) causes 3.85 MPa of wafer stress. FIG. 4B also illustrates that as the value of angles θ₁₂ and θ₃₄ decreases, the amount of wafer stress decreases as well. As demonstrated by FIG. 4B, when angles θ₁₂ and θ₃₄ are at or near zero, the amount of wafer stress is reduced by around 20%.

In further implementations of the invention, a second support plate or ring may be mounted at an opposite end of the wafer support rods relative to the first support plate or ring. This provides a structure in which the wafer support rods are sandwiched between two support plates or rings.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. An apparatus comprising:
a circular base;
a first wafer support rod mounted at a first position proximate a perimeter of the circular base;
a second wafer support rod mounted at a second position proximate the perimeter of the circular base, wherein an angle θ₁₂ formed between the first position and the second position relative to a center of the circular base is less than 60°;
a third wafer support rod mounted at a third position proximate the perimeter of the circular base; and
a fourth wafer support rod mounted at a fourth position proximate the perimeter of the circular base, wherein an angle θ₃₄ formed between the third position and the fourth position relative to the center of the circular base is less than 60°;
wherein an angle θ₁₄ formed between the first position and the fourth position relative to the center of the circular base is less than or equal to 180°.

2. The apparatus of claim 1, wherein the circular base comprises a support plate.

3. The apparatus of claim 2, wherein the support plate comprises a material selected from the group consisting of quartz, silicon, and silicon carbide.

4. The apparatus of claim 1, wherein the circular base comprises a support ring.

5. The apparatus of claim 4, wherein the support ring comprises a material selected from the group consisting of quartz, silicon, and silicon carbide.

6. The apparatus of claim 1, wherein the wafer support rods include an array of grooves adapted for receiving an array of semiconductor wafers.

7. The apparatus of claim 1, wherein the wafer support rods comprise a material selected from the group consisting of quartz, silicon, and silicon carbide.

8. The apparatus of claim 1, wherein the angle θ₁₂ is around 20°.

9. The apparatus of claim 1, wherein the angle θ₃₄ is around 20°.

10. The apparatus of claim 1, further comprising a second circular base mounted on an opposing end of the first, second, third, and fourth support rods relative to the circular base.

11. The apparatus of claim 1, wherein the angle θ₁₂ is less than or equal to 45°.

12. The apparatus of claim 1, wherein the angle θ₃₄ is less than or equal to 45°.

13. The apparatus of claim 1, wherein the angle θ₁₂ is less than or equal to 20°.

14. The apparatus of claim 1, wherein the angle θ₃₄ is less than or equal to 20°.

15. An apparatus comprising:
a circular base;
a first wafer support rod mounted at a first position proximate a perimeter of the circular base;
a second wafer support rod mounted at a second position proximate the perimeter of the circular base, wherein an angle θ₁₂ formed between the first position and the second position relative to a center of the circular base is around 20°;
a third wafer support rod mounted at a third position proximate the perimeter of the circular base; and
a fourth wafer support rod mounted at a fourth position proximate the perimeter of the circular base, wherein an angle θ₃₄ formed between the third position and the fourth position relative to the center of the circular base is around 20°;
wherein an angle θ₁₄ formed between the first position and the fourth position relative to the center of the circular base is less than or equal to 180°.

16. The apparatus of claim 15, further comprising a semiconductor processing tool that houses the circular base and the first, second, third, and fourth wafer support rods.
